(19) United States
(12) Patent Application Publication
(10) Pub. No.: US 2026/0129808 A1
(43) Pub. Date: May 7, 2026

(54) DUAL PURPOSE COOLING IN COMPUTER MODULES

(71) Applicant: Nvidia Corporation, Santa Clara, CA (US)

(72) Inventors: John Franz, Tomball, TX (US); Tahir Cader, Spokane Valley, WA (US); Elad Mentovich, Tel Aviv (IL); Yuri Berk, Kiryat Tivon (IL); Isabelle Cestier, Haifa (IL)

(21) Appl. No.: 18/939,254

(22) Filed: Nov. 6, 2024

(51) Int. Cl. H05K 7/20

(52) U.S. Cl. CPC H05K 7/20809; H05K 7/20254; H05K 7/20272; H05K 7/20327; H05K 7/2079; H05K 7/20818

(57) ABSTRACT

Systems and methods herein are for dual purpose cooling for a computer module that may include a device cooling loop which may be configured to cool computing features of the computer module. The systems and methods herein may include an interconnect cooling loop, provided together with the device cooling loop, where the interconnect cooling loop may be configured to reduce, by at least a predetermined threshold, electrical resistance of interconnect features of the computer module.

### TECHNICAL FIELD

At least one embodiment pertains to cooling in computer environments such as datacenters.

### BACKGROUND

Computer environments such as datacenters may be subject to liquid cooling. A method of liquid cooling may include use of a single-phase treated water or propylene glycol mixture as media to cool computing features within a computer module. The focus may be on high-power density components such as processors and other computing circuitry, including graphics processing units (GPUs), central processing units (CPUs), data processing units (DPUs), memory, switches, and power regulators. The media used to cool such components may be limited by a freeze point in combination with a risk of condensation. Such cooling may not address interconnect features used with the processors and the other computing circuitry, and may not be able to address interconnect features to enable a predetermined data transmission rate.

### BRIEF DESCRIPTION OF DRAWINGS

FIG. 1 is an illustration of a system subject to dual purpose cooling that includes cooling for interconnects, in at least one embodiment;

FIG. 2A is an illustration of aspects of a secondary or device cooling loop that is associated with a primary cooling loop and that is part of a dual purpose cooling that includes a separate interconnect cooling loop for interconnect features in a computer module, in at least one embodiment;

FIG. 2B is an illustration of aspects of an interconnect cooling loop of dual purpose cooling in a computer module, in at least one embodiment;

FIG. 2C is an illustration of aspects for a design sub-system and a manufacturing sub-system to prepare a secondary or device cooling loop and an interconnect cooling loop as part of a dual purpose cooling in a computer module, in at least one embodiment;

FIG. 2D illustration of further aspects for a manufacturing sub-system to prepare a secondary or device cooling loop and an interconnect cooling loop as part of a dual purpose cooling in a computer module, in at least one embodiment;

FIG. 3 is an illustration of further computer module features incorporating the first and interconnect cooling loops for dual purpose cooling, in at least one embodiment;

FIG. 4 illustrates rack aspects in a system for dual purpose cooling, according to at least one embodiment;

FIG. 5A illustrates a process flow for a system for dual purpose cooling, in at least one embodiment;

FIG. 5B illustrates yet another process flow for a system for dual purpose cooling, in at least one embodiment; and

FIG. 6 illustrates an example datacenter, in which at least one embodiment from FIGS. 1-5B may be used.

### DETAILED DESCRIPTION

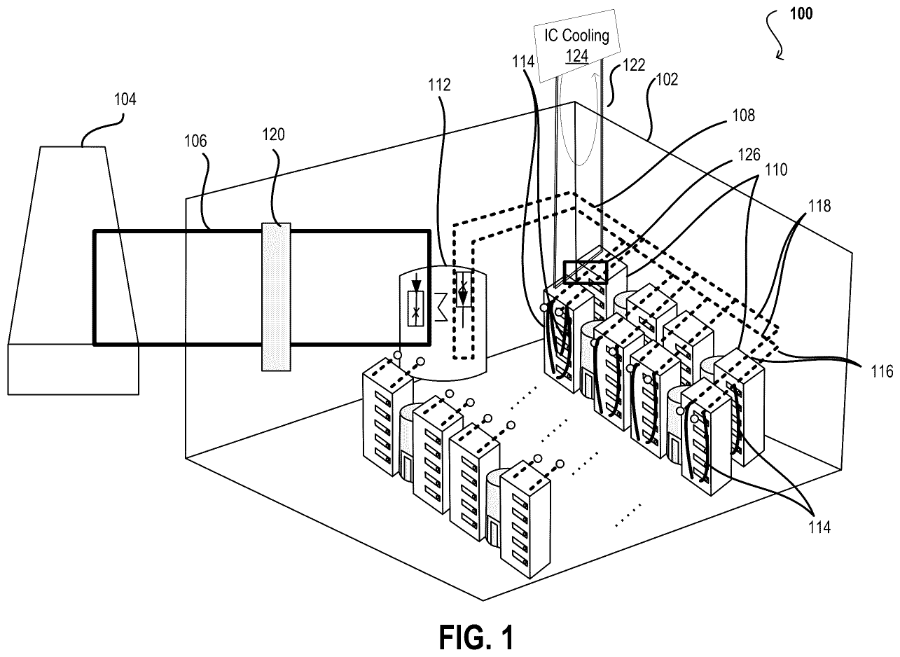

FIG. 1 is an illustration of an example system 100 subject to dual purpose cooling that includes cooling for interconnects, in at least one embodiment. To address limitations in liquid cooling in a datacenter, instead of reliance on only high-conductive materials such as metals and superconductors used for interconnect features and to improve interconnect performance in a linear manner, enhanced liquid cooling may be provided in the system. As used herein, the interconnect features may be conductive portions of a circuit board that may be between computing circuitry or computing features. For instance, the interconnect features may include metal traces, plated and non-plated through-holes, solder points, transmission lines, and electrically-insulating circuit board material over which such copper traces and solder points may lie. An interconnect feature may pass along sides and across the circuit board to contact between computing circuitry or features, and may include chip to chip interconnects, such as an NVlink® interconnect, a PCIe® high speed communication interconnect, among other interconnects that may exist on a circuit board.

The enhanced liquid cooling may use at least two distinct cooling loops, also referred to herein as an interconnect cooling loop for the interconnect features and a secondary or device cooling loop for the computing circuitry or features, which may include processors, network adapters (including a Network Interface Controller (NIC)), input/output (I/O) devices, peripheral devices or components on a system-on-chip (SoC), devices and components at which a signal is received or measured, or any other computing circuitry that may not only be used to only transmit signals.

The secondary or device cooling loop may be associated with a primary-to-secondary cooling loop infrastructure (including heat exchangers and coolant or fluid distribution units (CDUs)) provided to cool computing features and is different from the interconnect cooling loop used to cool interconnect features. The interconnect cooling loop may provide cooling for interconnect features that may include pathways, and may provide such cooling within a range of 0 to 123 degrees Kelvin (or less than zero degrees Centigrade (°C)). Further, the interconnect cooling loop is provided to maintain a temperature through the computer module, even for interconnect media therein that exits the computer module. As used herein, a computer module may be a server tray, box, or other enclosure having one or more circuit boards with processors and other computing circuitry, and with interconnect features. The enhanced liquid cooling can cause decrease in electrical resistance and decrease in electrical losses in the interconnect features as a temperature of the interconnect features is decreased and maintained in the decreased manner in the datacenter. In addition, the decrease in electrical resistance provides a decrease in power consumed in support of the decrease in electrical losses as a result of the interconnect cooling loop herein.

In one example, while the secondary or device cooling loop may be associated with a primary cooling loop of a datacenter and may interface with a heat exchanger and a cooling tower or other suitable cooling system of the primary cooling loop, the purpose of the device cooling loop may be to cool processors and other similar computing circuitry, referred to herein as computing features. The other similar computing circuitry are necessarily silicon-based devices, including application-specific integrated circuits (ASICs). In one example, however, the device (or secondary) cooling loop may, therefore, function at temperatures above 0° C., because such a temperature is suitable for heat removal from the computing features. The cooling of the interconnect features, on the other hand, by the interconnect cooling loop may cause the interconnect features to be subject to decreased electrical resistance and decreased electrical losses using an interconnect media (cryogenic coolant or refrigerant) that is at a temperature of less than −100° C.

Therefore, in at least one embodiment, the system and a supporting method herein is for maintaining single-phase cooling, in the device cooling loop, using water-based coolants to extract heat from silicon-based devices or computing features, while providing an interconnect cooling loop which functions at least substantially in a parallel to the device cooling loop for computing features that benefit electrically, such as interconnect features or non-silicon-based features. In one example, the interconnect cooling loop may route interconnect media capable of being at less than 100° C. to numerous sections of dense routed high speed signaling interconnect features of a computer module.

In doing so, the dual purpose cooling herein can address lower operation temperatures (of less than −100° C.) for interconnect features to achieve higher electrical modulation frequencies and lower power losses. Therefore, the dual purpose cooling for computer modules herein can address computing features forming the silicon-based devices and interconnect features formed of interconnects and other pathways. The device cooling loop herein can be associated with cooling the computing features and the interconnect cooling loop herein can be associated with addressing (such as, reducing or decreasing) electrical resistance and electrical losses of interconnect features. For instance, computing features that are silicon-based devices may be able to demonstrate performance benefits at temperatures that are above ° C., with heat removal performed in that region of temperatures; and, interconnect features may include conductors (such as, copper, stainless, aluminum, and other suitable thermally conductive materials that may be apparent upon review of this description) and may be able to demonstrate performance benefits in a cryogenic or near-cryogenic range of temperatures, including temperatures less than −100° C. Therefore, each of the device cooling loop and the interconnect cooling loop operate at different temperatures, pressures, and flow rates.

Therefore, the device or secondary cooling loop may different cooling media, such as water and propylene glycol-related (PG) as secondary media to cool the computing features using cold plates over the computing features, while the interconnect cooling loop may use special cooling media, such as refrigerants (including R1234Ze® and R1234YF®) and, particularly, cryogenic or other interconnect cooling media (including, liquid Nitrogen, liquid air, and liquid helium) to provide cooling over or under the interconnect features. A further benefit realized by the dual purpose cooling herein is the different exit temperatures of the device and the interconnect cooling loops, at respective exits from a computer module. For instance, the device cooling loop, being provided for cooling, may have a marked increase in temperature and may go from at least slightly over 0° C. to about 60° C., at its exit from a computer module because of absorbed heat from the computing features. Differently, the interconnect cooling loop can maintain an exit temperature of less than −100° C. (or substantially its inlet temperature at the computer module) as its purpose is to address electrical resistance and electrical losses of interconnect features. In addition, moisture barriers, o-ring seals, and backplane cooling may also be supported in the interconnect cooling loop to address condensation possibilities.

In at least one example, a change in temperature of the secondary media of a secondary cooling loop, between its inlet and exit with respect to a circuit board of a computer module, may be in the range of about 15° C. to 30° C. For instance, the secondary media may at an inlet of the computer module at about 20° C. and may exit at about 40° C. In another example, the secondary media may at an inlet of the computer module at about 45° C. and may exit at about 60° C. In yet another example, the secondary media may at an inlet of the computer module at about 17° C. and may exit at about 60° C. Here, the secondary media at the inlet having a temperate of 17 the secondary media may at an inlet of the computer module at about 20° C. and may exit at about 40° C. may be considered at a low end of its temperature for inlet, primarily to prevent condensation within a computer module. In addition, the temperature of 60° C. at the exit may represent a maximum allowable temperature for the secondary media to prevent issues of burns to human skin or other sensitivities, when servicing components. As such, these example temperatures are for guidance as common boundaries but may be changed as required for functionality and within the context appreciated by the descriptions herein.

Therefore, cooling in computer modules may be intended to only address computing features, where heat generated from silicon-based devices is targeted and removed, without regard (specifically, without targeting) interconnect features. Differently, the dual purpose cooling herein uses an interconnect cooling loop at cryogenic or near-cryogenic range of temperatures to address electrical resistance and electrical losses of interconnect features, in addition to the device cooling loop associated with cooling the computing features. Further, although some heat may be transferred from the silicon-based devices to the interconnect cooling loop, the interconnect cooling loop is targeted, by a media path, to address the electrical resistance and electrical losses of interconnect features and is not targeted towards computing features addressed by cold plates of the device cooling loop.

FIG. 1 is a block diagram of an example system 100 of a datacenter having a cooling system subject to improvements described in at least one embodiment. The datacenter may be within one or more rooms 102 and may have racks 110 and auxiliary equipment to house one or more servers on one or more server trays having circuit boards therein, which may be altogether referred to herein as computer modules. The datacenter may be supported by a cooling tower 104 located external to the datacenter. The cooling tower 104 may dissipate heat from within the datacenter by acting on a primary cooling loop 106. Further, a cooling distribution unit (CDU) 112 may be used between the primary cooling loop 106 and a secondary cooling loop 108 to enable extraction of the heat from the secondary cooling loop 108 to the primary cooling loop 106. The secondary cooling loop 108 can access various plumbing all the way into the server tray as required, in an aspect.

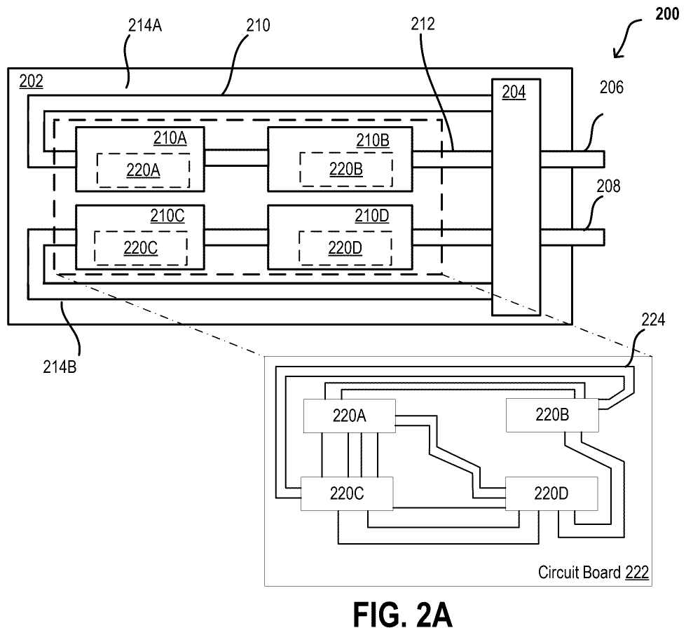

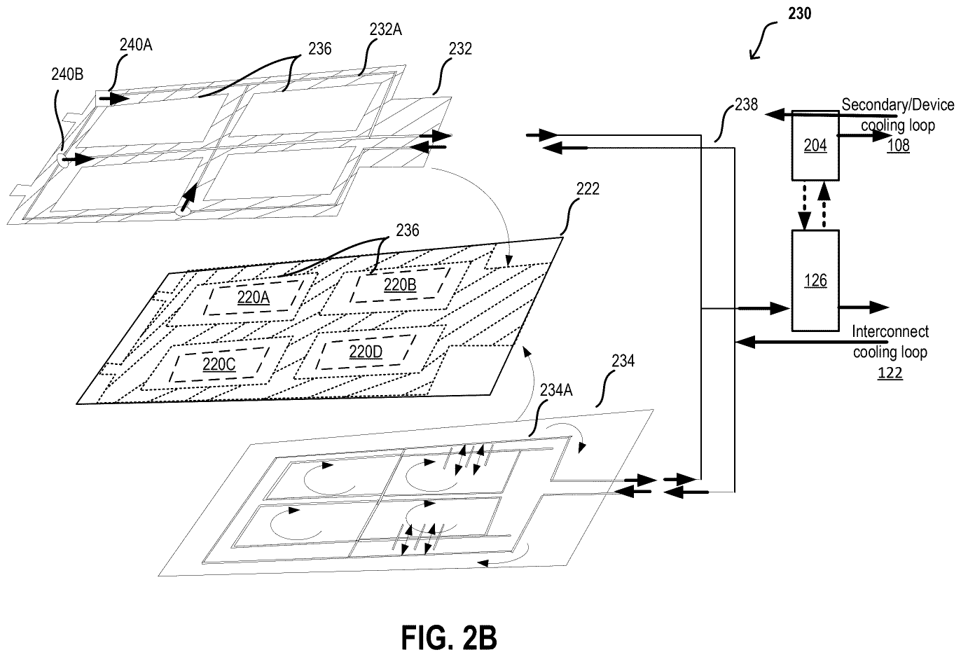

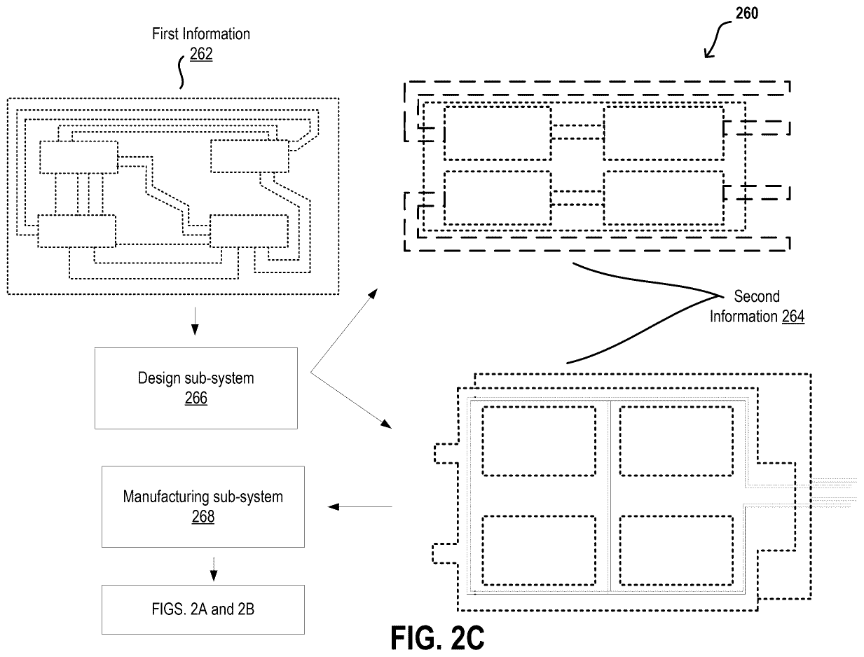

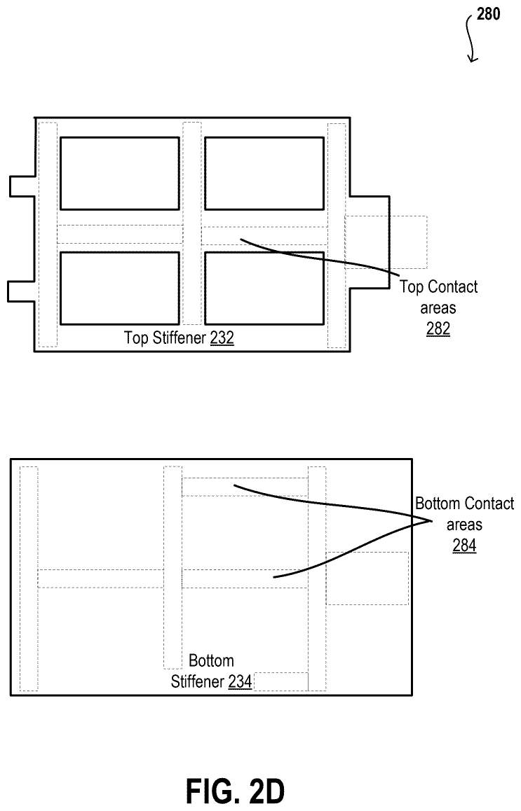

The primary and secondary cooling loops 106, 108 are illustrated as line drawings, but a person of ordinary skill would recognize that one or more plumbing features may be used. In an instance, flexible polyvinyl chloride (PVC) pipes may be used along with associated plumbing to move the media along in each of the primary and secondary cooling loops 106, 108. One or more pumps, in at least one embodiment, may be used to maintain pressure differences within the primary and secondary cooling loops 106, 108 to enable the movement of a media (such as, a primary media or a secondary media that may be a coolant or refrigerant) according to temperature sensors in various locations, including in the room, in one or more racks 110, and/or in server boxes or server trays within the racks 110. As used herein, at least the secondary or device cooling loop 108, which is associated with a primary cooling loop 106, may be configured to cool computing features of the computer module, as detailed further in one or more of FIGS. 2A-6 herein.

In at least one embodiment, a secondary media in a secondary cooling loop 108 have an inlet temperate of less than 0° C., but above −100° C. In such circumstances, an interconnect cooling loop for interconnect features uses an interconnect media that maintains an inlet temperature and an exit temperature of less than −100° C. In one example, a primary media in the primary cooling loop 106 may be used to cool the secondary media in the secondary or device cooling loop 108, and which is different than the interconnect cooling loop of a dual purpose cooling system for interconnect features. The primary media and the secondary media may be at least water and an additive, for instance, glycol or propylene glycol. In operation, each of the primary and the secondary cooling loops 106, 108 have their own media. In an aspect, the secondary media in the secondary cooling loops may be proprietary to requirements of the components in the server tray or racks 110.

The CDU 112 may be capable of sophisticated control of the primary and the secondary media, independently or concurrently, in the primary and the secondary cooling loops 106, 108. For instance, the CDU may be adapted to control the flow rate of a secondary media of the secondary cooling loop 108 so that the secondary media may be appropriately distributed to extract heat generated within the racks 110. Further, more flexible tubing 114 is provided from the secondary cooling loop 108, relative to the primary cooling loop, to allow entry to each computer module and to provide secondary media to the computing features therein. In the present disclosure, the computing features may be used interchangeably to refer to the heat-generating components that benefit from the present datacenter cooling system.

The tubing 118 illustrated in FIG. 1 and that may form part of the secondary cooling loop 108 may be referred to as room manifolds. Separately, additional tubing 116 extending from such tubing 118 may also be part of the secondary cooling loop 108 but may be referred to as row manifolds. Still further tubing 114 illustrated in FIG. 1 may enter the racks as part of the secondary cooling loop 108, but may be referred to as rack cooling manifold. Further, the row manifolds 116 extend to all racks along a row in the datacenter. The plumbing of the secondary cooling loop 108, including the manifolds or tubing 118, 116, and 114 may be improved by at least one embodiment of the present disclosure. An optional chiller 120 may be provided in the primary cooling loop within datacenter to support cooling before the cooling tower. To the extent additional loops exist in the primary control loop, a person of ordinary skill would recognize reading the present disclosure that the additional loops provide cooling external to the rack and external to the secondary cooling loop; and may be taken together with the primary cooling loop for this disclosure.

In at least one embodiment, in operation, heat generated within server trays of the racks 110 may be transferred to a secondary media exiting the racks 110 via flexible tubing 114 of the row manifold of the secondary cooling loop 108. Pertinently, secondary media (in the secondary cooling loop 108) from the CDU 112, for cooling the racks 110, moves towards the racks 110. The secondary media from the CDU 112 passes from on one side of the room manifold having tubing 118, to one side of the rack 110 via row manifold 116, and through one side of the server tray via provided tubing 114. Spent secondary media (or exiting secondary media carrying the heat from the computing features) may exit out of another side of the server tray (such as, enters left side of the rack and exits right side of the rack for the server tray after looping through the server tray or through components on the server tray). The spent secondary media that exits the server tray or the rack 110 comes out of different side (such as exiting side) of tubing 114 and moves to a parallel, but also exiting side of the row manifold 116. From the row manifold 116, the spent secondary media moves in a parallel portion of the room manifold formed of a tubing 118 going in the opposite direction than the incoming secondary media (which may also be the renewed secondary media), and towards the CDU 112. Further, the spent secondary media may have an exit temperature of above 0° C. and may specifically be in the range of 40-70° C.

In at least one embodiment, the spent secondary media may exchange its heat with a primary media in the primary cooling loop 106 via the CDU 112. The spent secondary media may be renewed (such as relatively cooled when compared to the temperature at the spent secondary media) and ready to be cycled back to through the secondary or device cooling loop 108 to the computing features or components. Various flow and temperature control features in the CDU 112 enable control of the heat exchanged from the spent secondary media or the flow of the secondary media in and out of the CDU 112. CDU 112 is also able to control a flow of the primary media in primary cooling loop 106.

A system for dual purpose cooling herein may be provided, in part, for cooling within one or more computer modules of one or more racks 110. The system may include a device or secondary cooling loop 108 that interfaces with a primary cooling loop 106 and is configured to cool computing features of the computer module, as detailed in one or more of FIGS. 2A-6 herein. The system may include an interconnect cooling loop 122 that is distinct from the secondary or device cooling loop 108 and from the primary cooling loop 106. The interconnect cooling loop 122 may be configured to reduce, by at least a predetermined threshold, electrical resistance of interconnect features of the computer module. In at least one embodiment, the interconnect cooling loop 122 may be allowed to interface with at least the secondary cooling loop 108 to provide further exchange of heat for the secondary cooling loop 108. This may be in addition to the primary cooling loop 106. The interconnect cooling loop 122 is distinct from the primary and secondary cooling loops 106, 108 at least because it may be associated with a distinct interconnect media having an exit temperature of less than −100° C. The exit temperature is in reference to exit from a computer module of the one or more racks 110.

Further, as illustrated, the interconnect cooling loop 122 may be associated with a distinct interconnect (IC) cooling system 124. The IC cooling system 124 may include a reservoir and a heat exchange mechanism for cooling returned interconnect media. The IC cooling system 124 may be located internally or externally relative to a datacenter and to a datacenter room. Further, the IC cooling system 124 may be configured to provide the interconnect media for the interconnect cooling loop with an inlet temperature of less than −100° C. The inlet temperature is in reference to an entry at the computer module of the one or more racks 110. These provisions of the interconnect cooling loop 122 may be distinct from the primary and the secondary cooling loops 106, 108, having associated therewith a primary and a secondary media having an inlet temperate that is typically higher than 0° C., but may be of less than 0° C. but above −100° C. In at least one example, there may be a mandatory minimum of 100° C. of difference in inlet temperatures between the secondary cooling loop 108 and the interconnect cooling loop 122.

Further, the interconnect cooling loop 122 may be configured to be in a series configuration with respect to at least one secondary cooling loop 108. The series configuration may be provided within a series configuration module 126, which may include a heat exchanger between the interconnect cooling loop 122 and the secondary cooling loop 108, at the exit of each of the interconnect cooling loop and of the secondary cooling loop 108. Therefore, the series configuration module 126 may be located within a computer module or at its exit, but towards and exit side of the interconnect cooling loop and of the secondary cooling loop. The series configuration module 126 can enable or support an interconnect media used in the interconnect cooling loop 122 to be in a first state to perform the reduction in the electrical resistance of the interconnect features of a computer module and can enable or support a second state or a phase change from the first state to the second state to perform the heat exchange with the at least one secondary cooling loop 108. Further, even though illustrated as outside a rack, the interconnect cooling loop 122 is particular able to reach interconnect features that are within a computer module.

FIG. 2A is an illustration of aspects 200 of a secondary or device cooling loop that is associated with a primary cooling loop and that is part of a dual purpose cooling that includes a separate interconnect cooling loop for interconnect features in a computer module. As used in FIG. 2A, the secondary or device cooling loop 214A, 214B of the dual purpose cooling may be provided to extend a device or secondary cooling media from the secondary cooling loop 108 provided to a rack 110 in FIG. 1 The aspects 200 may include server-level features and may include a computer module 202 having at least one server manifold 204 to allow entry and egress of a secondary media of a secondary cooling loop 108, from a rack 110. The server manifold 204 may include separate channels for inlet and for exit of secondary media of the secondary cooling loop 108, which is illustrated as an extension from the rack to be secondary cooling loops 214A, 214B, within the computer module.

The secondary media may enter from a rack manifold, via inlet pipe 206 and may exit via outlet pipe 208. The secondary media, on the server side may travel via inlet line 210, through one or more cold plates 210A, 210B, and via outlet line 212 to the manifold 204. This represents at least one or multiple secondary cooling loops 214A, 214B within the server tray or box serving as a computer module 202. These multiple secondary cooling loops 214A, 214B may be an extension of the secondary cooling loop 108 interfacing with the primary cooling loop 106 as they provide the same or substantially the same secondary media from the secondary cooling loop 108 to the cold plates 210A-210D. In at least one embodiment, the cold plates 210A-210D are associated with at least one computing component or feature 220A-220D. In addition, while illustrated as different cold plates, the illustrated cold plates 210A-210D may be part of a large single cold plate structure have integrated contact points that are specifically over the underlying computing features 220A-220D. A computing feature 220A-220D may include processors, memories, and switches or regulators. In one example, the processors may include graphics processing units (GPUs), central processing units (CPUs), data processing units (DPUs), and ASICs.

In at least one embodiment, even though illustrated as having one inlet and one outlet or exit for inlet line 210 and for outlet line 212, there may be multiple intermediate lines, such as flexible pipes associating the cold plate with the respective inlet line 210 and outlet line 212. In at least one embodiment, the intermediate lines directly couple the cold plate to the manifold 204 are provided inlet and outlets for such connections. In at least one embodiment, media adapters are provided to enable such coupling. In at least one embodiment, the media adapters are sized to the inlet and outlet provisions in the cold plate and the manifold 204.

FIG. 2A also illustrates that the aspects 200 may include a circuit board 222 having interconnect features 224 on a first side (top side, as illustrated) and on a second side (bottom side, similar features as the top side illustrated or soldered features relative to the top side). The interconnect features 224 may couple one or more of the computing features 220A-220D together. The interconnect features 224 may include metal traces, plated and non-plated through-holes, solder points, transmission lines, and electrically-insulating circuit board material over which such copper traces and solder points may lie. As the computing features 220A-220D may be high-power density devices, secondary media used to cool such devices may be limited by their freeze point combined with risks of condensation.

Further, high-conductive materials such as metals and superconductors may be used for interconnecting features 224, with improvement to performance in a linear manner, from reduced electrical resistance and reduced electrical losses, as temperature therein decreases. The temperature reduction required to demonstrate such benefits may be different than that of high-power density devices, such as the silicon-based devices that may perform better at temperatures above 0° C. Therefore, to improve data transmission rate through interconnect features 224 that associate together the high-power density devices, the interconnect cooling loop 122 herein provides substantially lower temperatures (such as, −100° C.) that can be maintained from an entry to an exit media path of an interconnect media of the interconnect cooling loop 122.

The interconnect cooling loop 122 herein may be provided as a parallel media path with the secondary cooling loop 108; 214A; 214B using equipment focused on delivering interconnect media at less than −100° C. The interconnect media may be delivered to sections of a circuit board 222 having densely-routed high speed signaling interconnects, as part of the illustrated interconnect features 224 that are shown in a less dense pattern for illustrative purposes only. Therefore, the secondary cooling loop 108; 214A; 214B may be maintained with a single-phase cooling approach using water-based coolants to extract heat from the high-powered devices, while the interconnect cooling loop 122 may be able to operate in a two-phase cooling approach. For instance, in a first phase that may be liquid phase of the interconnect media, the interconnect features 224 may be cooled and, in a second phase that may be vapor phase of the interconnect media, a heat exchange may be enabled between the interconnect cooling loop 122 and the secondary cooling loop 108; 214A; 214B. At least the heat exchange may be performed in a series configuration module 126. Therefore, in one example, the device media and the interconnect media are a same media and is used serially or subsequently and undergo a two-phase transformation process.

Further, existing single-fluid cryogenic coolant and refrigerant-based options may be unable to simultaneously balance cooling needs of computing features 220A-220D, while optimizing performance of interconnect features 224. The interconnect features 224 may include high-speed interconnect routing within the circuit board 222 and a connected infrastructure that may be operating at a range of temperatures that may be between room and cryogenic temperatures. As illustrated with respect to FIGS. 1 and 2A, the two distinct cooling loops (interconnect and secondary or device cooling loops) may circulate different media within a server tray, box, or computer module 202, while keeping the different media in a respective and separate media path. The different media may operate at different temperatures, pressures and flow rates. The different media may not mix but may be purposefully used for heat exchange purposes therebetween using the series configuration module 126. For instance, the heat exchange performed between the two distinct cooling loops may be for optimal temperature regulation with respect to the secondary cooling loop 108; 214A; 214B using exiting interconnect media of the interconnect cooling loop 122. Pertinently, this may be beneficial in computer modules that are within a larger rack, where distances and ambient temperatures may have an effect on an ability of the secondary cooling loop 108 to maintain the cooling temperatures required in the system.

In at least one example, the two distinct cooling loops may be, individually, closed loop and pumped systems that can maintain beneficial attributes of high-volume existing single-phase pumped media therein. This extends an ability to provide service, reliability and dimensional configurations for the individual ones of the two distinct cooling loops, making it more amenable to greater adoption among in a datacenter. In one example, a first closed cooling loop may be provided in parallel and to work concurrently with a second closed cooling loop within infrastructure of a datacenter. As used herein, infrastructure of a datacenter, for cooling purposes, may include one or a combination cooling units for one or more of liquid, air, or other media-related cooling. The cooling units may include cold plates, manifolds or tubing, pumps, fans, Computer Room Air Conditioners (CRAC), in-row cooling units, liquid cooling systems, airflow management systems, other suitable cooling units configured to move or remove heat from a datacenter. The first closed cooling loop may include a first pumped cooling media to extract heat from computing features in the infrastructure. The second closed cooling loop may include a second pumped cooling media to reduce, by a predetermined threshold, electrical resistance and/or electrical loss of interconnect features in the infrastructure.

In at least one implementation, a secondary cooling loop 108; 214A; 214B may be used to capture a largest portion of heat generated within the system, while targeting the computing features 220A-220D. For instance, it is possible to capture ambient heat that may be other than the targeted computing features 220A-220D. Therefore, it is possible to capture about 80-90% of heat generated from a computer module or a rack by one or more of the secondary cooling loops 108; 214A; 214B. This is even though the secondary cooling loop 108; 214A; 214B may operate at temperatures that are greater than 0° C. and even though the secondary cooling loop 108; 214A; 214B may operate using a water-based media. Although, the secondary media of such secondary cooling loops may include a PG mixture with water, which may be able to reduce freezing risks to a degree.

Differently, the interconnect cooling loop 122 herein may be used to target passive devices of the interconnect features 224, such as the copper traces, plated and non-plated through holes, solder points, transmission lines, and electrically-insulating circuit board material over which such copper traces and solder points may lie. These interconnect features 224 may also include high-bandwidth interconnects that may not generate a large percentage of heat compared to the computing features 220A-220D. Nonetheless, the interconnect cooling loop 122 targets a reduction in electrical resistance of the interconnect features 224, by at least a predetermined threshold, of the electrical resistance and also targets reduction in other included electrical losses of a computer module 202. The interconnect media in the interconnect cooling loop 122 may be an environmentally safe media that may be capable of being pumped at −100° C. or colder, and may be maintained at −100° C. or colder at its exit from a computer module.

FIG. 2B is an illustration of aspects 230 of the interconnect cooling loop of dual purpose cooling in a computer module, in at least one embodiment. As illustrated, while the secondary cooling loop 108; 214A; 214B may be used to absorb heat from a computing feature 220A-220D, the interconnect cooling loop 122 may use metal lines on one or more stiffener plates 232, 234. For instance, a first stiffener plate may be a top side stiffener plate 232 that may be provided over a first side (such as, a top side) of a circuit board 222. The circuit board 222, as illustrated in FIG. 2A, may include the interconnect features 224 on a first side and on a second side of the circuit board. The stiffener plates may be provided from aluminum or graphene materials.

A bottom side stiffener plate 234 may be provided under the second side of the circuit board 222. The interconnect cooling loop 122 may be provided using inlet and exit media paths for the top side stiffener plate 232 and for the bottom side stiffener plate 234. On the stiffener plates 232, 234, the media paths provided may be one or more metal lines 232A, 234A, of the interconnect cooling loop. These copper or other metal (or thermally conductive) lines 232A, 234A may substantially align with the interconnect features 224 and can enable the reduction, by at least the predetermined threshold, of the electrical resistance of the interconnect features 224. Further, in at least one example, although illustrated on a top surface of the top side stiffener plate 232, the thermally conductive line 232A of this top side stiffener plate 232 may be so that they are contacting the interconnect features 224 of the top side of circuit board 222. For instance, the top side stiffener plate 232 illustrated is turned over and then associated with the top side of the circuit board 222. In an example, it is also possible to allow cooling to occur through the stiffener plate itself.

Further, at least the top stiffener plate 232 may be such that it incorporates open areas 236 to accommodate one or more cold plates 210A-210D of the secondary cooling loop 108; 214A; 214B therethrough. For instance, the cold plates 210A-210D may extend in a plan view, from the surface of a computing feature 220A-220D and through the open areas 236. While the cold plates 210A-210D may be provided in association with at least one of the computing features 220A-220D to absorb heat from the at least one of the computing features, the thermally conductive lines 232A, 234A of the stiffener plates 232, 234 enable the reduction, by at least the predetermined threshold, of the electrical resistance of the interconnect features 224. As illustrated, both features may co-exist in the computer module.

In at least one embodiment, a series configuration module 126 may incorporate a heat exchanger and may be located within a computer module or a rack. The series configuration module 126 enables an interconnect cooling loop 122 to interface with a secondary cooling loop 108. For instance, while inlet of the interconnect media and the secondary media in the interconnect cooling loop 122 and the secondary cooling loop 108 may pass through unimpeded, the interconnect media of the exit part of the interconnect cooling loop 122 can be allowed to interface with the secondary media at the exit part of the secondary cooling loop 108, via a heat exchanger. As the interconnect media, at the exit part of the interconnect cooling loop 122, from at least a circuit board 222 of a computer module is still under −100° C., and as the secondary media at the exit part of the secondary cooling loop 108 may be at about than 60° C., there may be a beneficial heat exchange for the secondary cooling loop 108, prior to the primary cooling loop 106. Such an interaction may be also before the secondary cooling loop 108 is used to remove heat from other computer modules or racks, or for infrastructure cooling purposes.

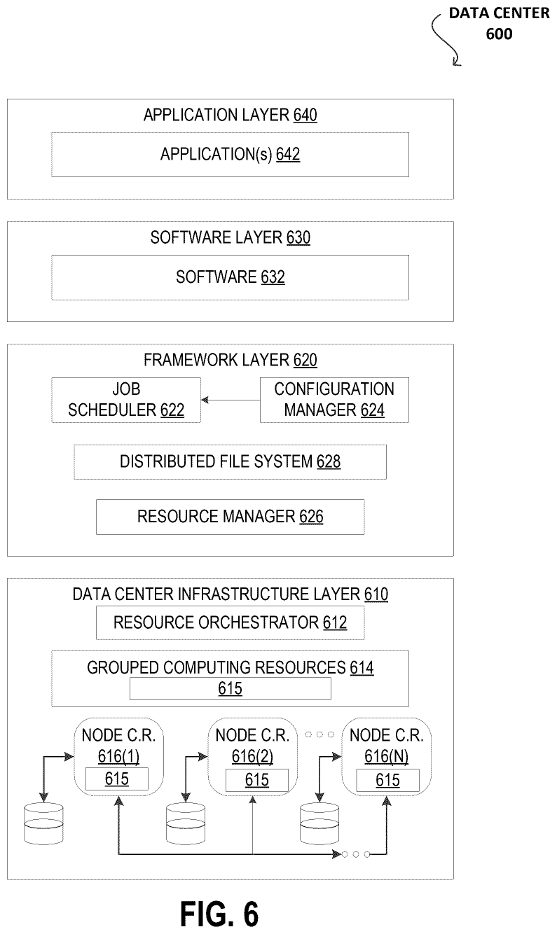

FIG. 2B also illustrates, relative to the circuit board 222 illustration in FIG. 2A, that the thermally conductive lines 232A, 234A are substantially aligned to the interconnect features 224 that are around the computing features 220A-220D. FIG. 2B also illustrates that a pump 240A or directional valves 240B may be provided to support a single phase or a two-phase media in the interconnect cooling loop. The pump or the direction valves may be controlled based in part on an input from a control system associated with the interconnect cooling loop. The control system may be performed using a processor and at least memory including instructions that when executed by the processor is able to utilize at least temperature monitored from an exit of the interconnect media to provide control on an inlet side of the interconnect cooling loop. The control system may use processor aspects as described with respect to at least FIG. 6 herein. The pump 240A may be used to pump a single phase media of the interconnect cooling loop 122 but a directional valve 240B may be used to allow vapor phase of the interconnect media to continue in a single direction to exit a computer module or to perform the heat exchange with the secondary cooling loop. While the pump or directional valves may allow adjustment to the interconnect media, the control for the pump or directional valves may be provided from the control system. The two-phases may represent a two-phase transformation process.

FIG. 2B also illustrates that the media paths 238 may extend from a single media path of at least the interconnect cooling loop 122, once within the computer module 202. This allows targeting of a first one of the interconnect features 224 on the first side (such as, a top side) of the circuit board 222 and of a second one of the interconnect features on the second side (such as, a bottom side) of the circuit board 222. Therefore, it is possible to reduce, by at least the predetermined threshold, the electrical resistance of the interconnect features 224 by predetermined flow rates or temperatures for an interconnect media of the interconnect cooling loop 122 that is provided from both sides of a circuit board 222 in a simultaneous manner.

In at least one embodiment, the top and bottom stiffeners 232, 234 are relatively thin in comparison to a top side cold plate 210A-210B or a large single cold plate format that may integrate the individual cold plates 210A-210B together. For instance, the top and bottom stiffeners 232, 234 may each be about 5 millimeters (mm) to 9 mm in height. The large single cold plate or the individual cold plates may support an approximately 20 mm of clearance to a top side of a circuit board to accommodate a cold plate. The interconnect media of the interconnect cooling loop may require a lesser flow volume relative to the secondary media of the secondary cooling loop. This may be particularly because the secondary cooling loop may be intended for heat extraction and may cause the secondary media therein to expand, while the interconnect cooling loop is intended to improve performance of the interconnect features without substantial heat extraction (and without expansion) in at least the areas over the interconnect features or within the cold plate. These dimensions may not apply to the series configuration module 126, which can allow exchange of heat from the secondary cooling loop to the interconnect cooling loop.

FIG. 2C is an illustration of aspects 260 for a design sub-system and a manufacturing sub-system to prepare a secondary or device cooling loop and an interconnect cooling loop as part of dual purpose cooling, in at least one embodiment. A design sub-system 266 and a manufacturing sub-system 268 may be part of a system of one or more circuits that may include at least a processor and a memory having instructions to be executed by the processor to perform functions of design and manufacturing. For instance, the design sub-system 266 can receive first information 262 that may pertain to at least a first layout and other specifications of computing features and of interconnect features for a circuit board. The design sub-system 266 can generate second information 264 that may pertain to a second layout and other specifications for a secondary or device cooling loop and an interconnect cooling loop. Then, the manufacturing sub-system 268 may use the second information 264 to prepare a secondary or device cooling loop and an interconnect cooling loop, for at least within a computer module, as part of the dual purpose cooling herein. Therefore, one or more of aspects 260 of the system having the design sub-system 266 and the manufacturing sub-system 268 may be performed using some features or all features of a datacenter 600 in FIG. 6.

A system having the design sub-system 266 and the manufacturing sub-system 268 can enable dual purpose cooling in a computer module, in part, by using first information 262 associated with computing features and interconnect features of the computer module as input and by generating second information 264. The first information 262 may include a first layout of the computing features 220A-220D and the interconnect features 224, and may also include one or more of a type of the computing features 220A-220D, the interconnect features 224, or predetermined heat or electrical specifications associated with the computing features 220A-220D and with the interconnect features 224. The system can then provide second information 264 for media paths 210, 212, 232A, 234A, 238 associated with a secondary cooling loop 214A; 214B and an interconnect cooling loop 122 within the computer module 202.

Although illustrated in FIG. 2C, the second information 262 may be in the form of specifications or code to be used to print, machine, or stamp-out features of at least the stiffeners and thermally conductive lines described herein with respect to an interconnect cooling loop 122. For instance, the specifications or code may be used with a three-dimensional (3D) printer, a Computer Numerical Control (CNC) machine, or other such manufacturing feature of a manufacturing sub-system 268 to prepare one or more stiffeners 232, 234 to be associated with a circuit board 222 having the computing features 220A-220D and the interconnect features 224. The manufacturing sub-system can also be used to prepare aspects of the secondary cooling loop 214A, 214B, for a cooling module that may include the cold plates 210A-210D integrated therewith. The cold plates 210A, 210B prepared in this manner can cool one or more of the computing features 220A-220D, once deployed, whereas the one or more stiffeners 232, 234 prepared in this manner can be used with the interconnect cooling loop 122 to reduce, by at least a predetermined threshold, electrical resistance of interconnect features 224 of the computer module 202.

Further, the specifications or code having the second information may include one or more of a layout for the media paths 210, 212, 232A, 234A, 238 having at least the interconnect cooling loop 122, a flow rate for at least an interconnect media of the interconnect cooling loop 122, or a predetermined phase or temperature range for the interconnect media in the interconnect cooling loop 122. The system herein, in part of the second information, may also provide the predetermined threshold for reduction in the electrical resistance of at least one of the interconnect features. This provision may be based in part on the first information. For instance, based in part on the first layout of the computing features 220A-220D and the interconnect features 224, a type of the computing features 220A-220D and the interconnect features 224, or predetermined heat or electrical specifications associated with the computing features 220A-220D and with the interconnect features 224, the system can determine the predetermined threshold to be achieved for reduction in the electrical resistance of at least one of the interconnect features.

In one example, the system can determine the predetermined threshold to be achieved using design features such as density, volume, length, or relationship (such as, distance) of the interconnect features, with respect to one or more computing features. Such design features can be used to also determine one or more of a flow rate and one or more inlet and exit temperatures to be associated with interconnect cooling loop 122. The system of one or more circuits can also provide the predetermined threshold based in part on the first information indicating that the at least one of the interconnect features is a high-speed interface between one or more of the computing features of the computer module. The predetermined threshold may be theoretical, as provided by the system, or may be realized by the system in the physical application described with respect to one or more of the figures herein.

FIG. 2D illustration of further aspects 280 for a manufacturing sub-system to prepare a secondary or device cooling loop and an interconnect cooling loop as part of dual purpose cooling, in at least one embodiment. Particularly, FIG. 2D illustrates that contact areas 282, 284 may be predetermined and provided for each of the stiffener plates 232, 234, as part of the second information 264, from the system described with respect to FIG. 2C. The contact areas (broken lines) may be customized based in part on the first information 262 providing layout of the circuit board 222. As illustrated, therefore, the contact areas 282, 284 are substantially aligned to the interconnect features 224 once in the physical application described with respect to one or more of the figures herein.

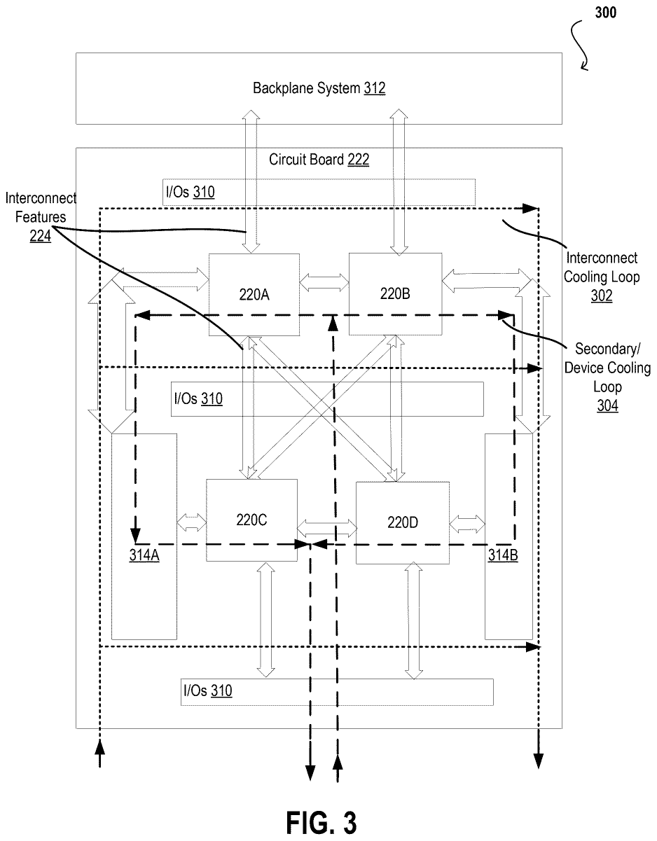

FIG. 3 is an illustration of further computer module features 300 incorporating the secondary or device and interconnect cooling loops for dual purpose cooling, in at least one embodiment. A secondary cooling loop 304 (broader broken lines) and an interconnect cooling loop 302 (finer broken lines) are illustrated to provide distinction of media paths between the two cooling loops 302, 304. The interconnect cooling loop 302 is illustrated as substantially over interconnect features 224, while the secondary cooling loop 304 is substantially over computing features 220A-220D, 314A, 314B. Further, while the interconnect cooling loop 302 and the secondary cooling loop 304 may pass over other features, the intent of each of these cooling loops is maintained to their respective requirements, which is for the secondary cooling loop 304 to cool the computing features 220A-220D, 314A, 314B and for the interconnect cooling loop 302 to reduce, by at least a predetermined threshold, electrical resistance of interconnect features 224.

Further, the view in FIG. 3 is an isometric view of a circuit board 222 which may include a large singular cold plate that resides on top of the circuit board 222 or with individual cold plates 210A-210D therein. In at least one example, it is possible to integrate, as part of the series configuration module 126, the top and bottom stiffener plates 232, 234 with the large singular cold plate and with the circuit board 222 nested in between. In this example, a secondary media may be provided through large singular cold plate and an interconnect media may be provided through the top and bottom stiffener plates 232, 234.

In an example, the computing features may be multiple GPUs and a single CPU, along with memory and switching or regulating components. The interconnect features may include voltage regulators, input/outputs (I/Os) 310, and the traces described throughout herein. While the secondary cooling loop 304 may pass close to or over such interconnect features, these interconnect features are only subject to an inefficient conduction path through many layers of thermal interfaces and through structural surfaces of the stiffeners. With temperature of a secondary media circulating in the secondary cooling loop 304 being in the range of 20° C. to 50° C., there may be reduced ability to deliver low enough temperatures to achieve enhanced signal speed performance in the I/Os 310 by the secondary cooling loop 304 alone.

FIG. 3 also illustrates that although interconnect features are generally illustrated between the computing features 220A-220D, 314A, 314B, some of these interconnect features may be high speed interconnect features, such as, GPU to CPU interconnect features, GPU to GPU interconnect features, memory interconnect features, I/O interconnect features, and GPU to outbound signal to a backplane system 312. The backplane system 312 may be a further circuit board to couple to connectors of the circuit board 222 having the computing features and the interconnect features.

Further, at least the cold plates and the top stiffener plates of the secondary cooling loop 304 and the interconnect cooling loop 302 may be overlaid on top of the computing features and the interconnect features. For at least the secondary cooling loop 304, the media path illustrated may be in a direction of entry of secondary media into a cold plate and exiting from the cold plate. The range of temperatures may be between 20° C. to 40° C. for the secondary media entering into cold plates associated with the computing features 220A, 220B (being GPUs). The secondary media may then pass across further computing features 220C, 220D that may include at least one CPU. As the secondary media passes across each GPU, its temperature rises. In at least one example, using a large singular cold plate, the media path illustrated for the secondary cooling loop 304 may include one or more 180 degree turns and may cover two GPUs before exiting the large singular cold plate. Although the high-speed interconnect features may be along the media path of the secondary cooling loop 302, the circuit board 222 and its substrate may not be a target of the cooling of the secondary cooling loop 302. The media temperature of the secondary cooling loop 302 alone may be too warm to provide any performance enhancement for the interconnect features 224, even if in indirect and inefficient associated with the interconnect features 224.

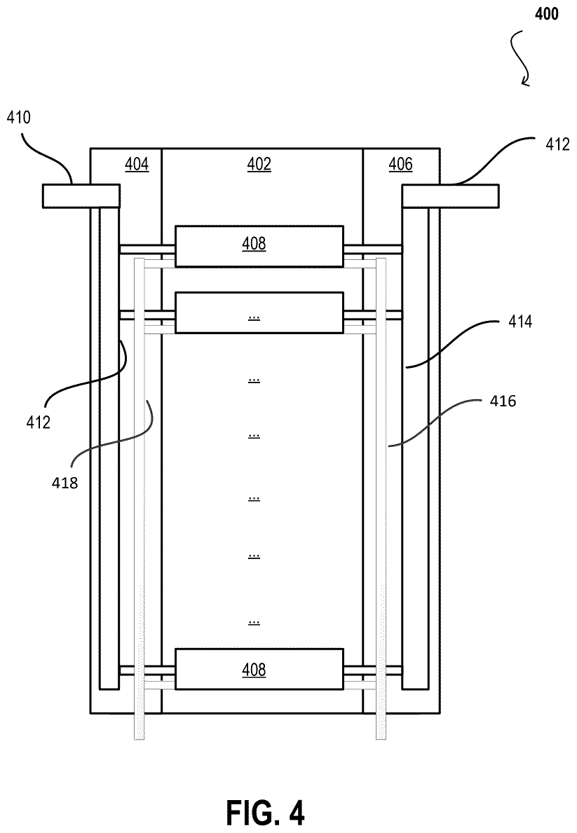

FIG. 4 illustrates rack aspects 400 in a system for dual purpose cooling, according to at least one embodiment. A rack 402 has brackets 404, 406, to enable hanging of one or more cooling loop components within the rack 402. In at least one embodiment, rack manifolds 412, 414 may be provided to guide secondary media from row manifolds to the computer modules 408 with the rack 402. The rack manifolds 412 may pass secondary media of a secondary cooling loop from the row manifolds through conduit 410, through the server trays or boxes 408, out of the egress row manifold 414, and back into the row manifold via the egress conduit associated with the rack manifold 412. The configurable cold plates may use higher pressure intermediate layers towards the bottom server tray or box of the illustrated computer modules 408, including server trays or boxes, if there is a need to increase pressure of coolant flow at that level. Alternatively, as coolant head pressure is higher at the bottom, the higher-pressure intermediate layers may be used in cold plates of the top server tray or boxes of the illustrated rack 402.

In addition, FIG. 4 illustrates that a separate manifold and other cooling loop components 416, 418 may be associated with the interconnect cooling loop that is distinct from the cooling loop components 410-414 of the secondary cooling loop. The other cooling loop components 416, 418 associated with the interconnect cooling loop may be attached to the same brackets 404, 406 or may be provided directly to one or more computer modules 408, as needed. An inlet manifold and an exit manifold for the interconnect cooling loop to a source may be provided, where the source may be an IC cooling system 124 or suitable feature, illustrated in and described with respect to FIG. 1. Further, although FIG. 4 illustrates that the intermediate cooling loop has an inlet and exit at a bottom of a rack 402, this is merely illustrative and the provisions for the inlet and the exit may be above or on the sides of the rack 402.

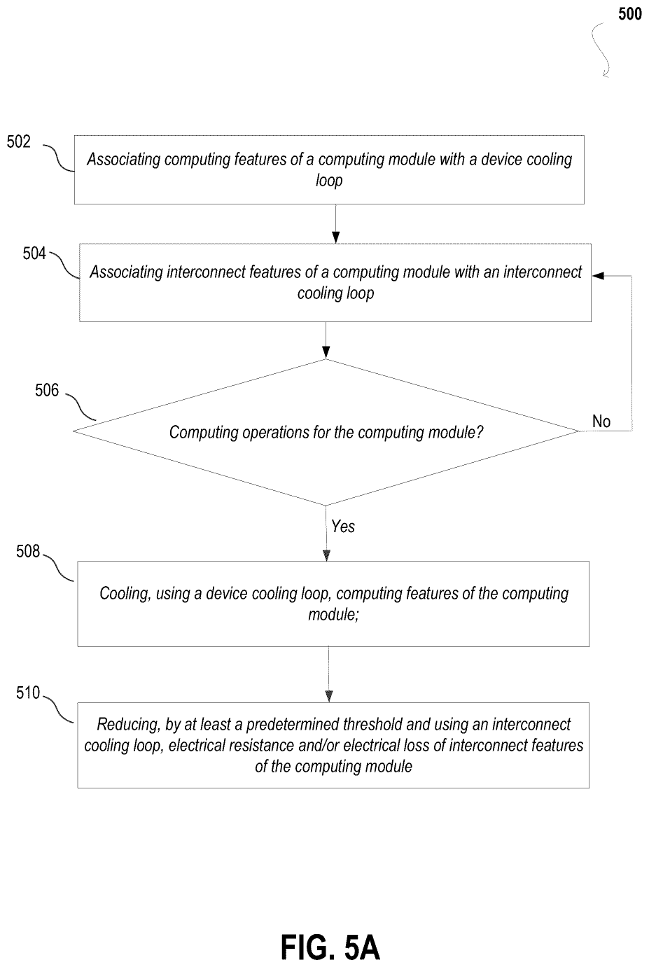

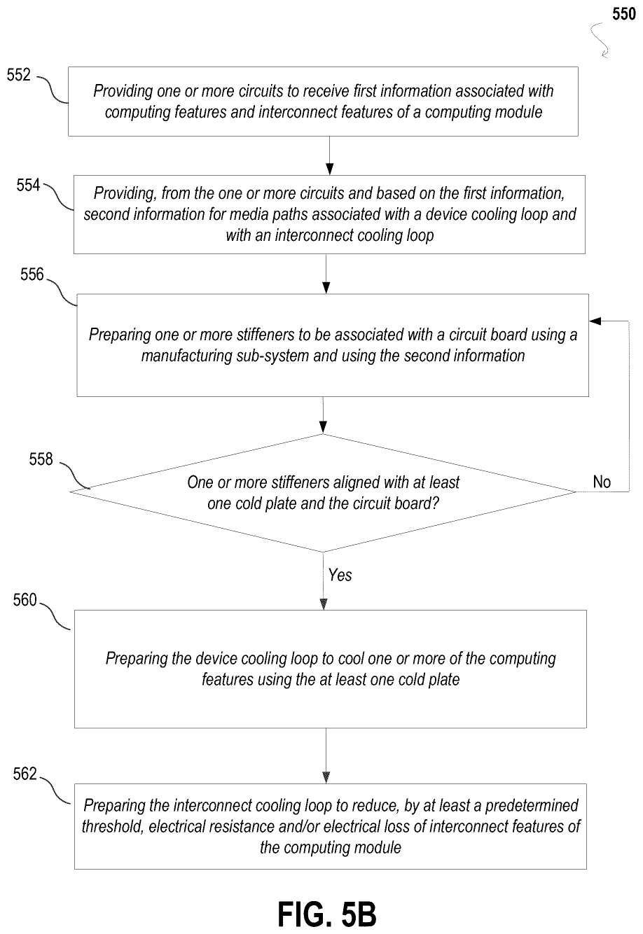

FIG. 5A illustrates a process flow or method 500 for a system for dual purpose cooling, in at least one embodiment. The method 500 may include associating 502 computing features of a computer module with a secondary or device cooling loop. This may be performed by attaching, to a circuit board, one or more cold plates or a large single cold plate of integrated multiple cold plates. This step may also include attaching the cold plates to manifolds and other features for the secondary or device cooling loop, which may be the secondary cooling loop described with respect to one or more of FIGS. 1-4. The method 500 may include associating 504 interconnect features of a computer module with an interconnect cooling loop, as also described with respect to FIGS. 1-4. This step may be performed by attaching, to the circuit board, one or more stiffener plates having thermally conductive lines for interconnect media of the interconnect cooling loop. Further, the order of the steps 502, 504 may be changed so that the stiffener plates are first associated with the circuit board, followed by the cold plate.

The method 500 may include determining or verifying 506 that there computing operations for the computer module. For instance, cooling may be performed either before or after computing operations are initiated for the computer module. In one example, the determining or the verifying 506 step may be performed for computing operations that may include starting up of the computer module or may include high-intensity workloads. The method 500 may include cooling 508, using a secondary or device cooling loop, the computing features of the computer module. In one example, the cooling 508 may occur at startup of the computer module or may occur at the start of a specific workload, such as, a high-intensity workload. The method 500 may include reducing 510, by at least a predetermined threshold and using an interconnect cooling loop, electrical resistance and/or electrical loss of interconnect features of the computer module. The reduction in step 510 may be performed together or separately from the cooling 508 step.

The method 500 may include a further step or sub-step where the secondary or device cooling loop may be associated with a secondary media having an exit temperature of above 0 degrees centigrade (° C.) and where the interconnect cooling loop may be associated with an interconnect media having an exit temperature of less than −100° C. The method 500 may include a further step or sub-step where the secondary or device cooling loop may be associated with a secondary media having an inlet temperate of less than 0° C. and above −100° C. In addition, the interconnect cooling loop may be associated with an interconnect media having an inlet temperature of less than −100° C.

The method 500 may include a further step or sub-step of providing the interconnect cooling loop in a series configuration with the secondary or device cooling loop. The method 500 may include a further step or sub-step for enabling, using the series configuration, heat exchange between the secondary or device cooling loop and the interconnect cooling loop. Further, an interconnect media used in the interconnect cooling loop may be in a first state to perform the reduction in the electrical resistance of the interconnect features of step 510. In addition, the interconnect media used in the interconnect cooling loop may be in a second state or may undergo a phase change from the first state to the second state to perform the heat exchange with the secondary or device cooling loop.

The method 500 may include a further step or sub-step of using the one or more cold plates in the secondary or device cooling loop, according to step 502 and which may be associated with at least one of the computing features to absorb heat from the at least one of the computing features. The method 500 may include a further step or sub-step of aligning one or more thermally conductive lines in the interconnect cooling loop with the interconnect features, as part of step 504, to enable the reduction, by at least the predetermined threshold, of the electrical resistance of the interconnect features.

The method 500 may include a further step or sub-steep of supporting, using a pump or directional valves, a single phase or a two-phase media in the interconnect cooling loop. This may be performed as part of the associating step 504 in the method 500. The method 500 may include a further step or sub-step of providing a circuit board having the interconnect features on a first side and on a second side of the circuit board. The method 500 may include a further steps or sub-steps of enabling a top side stiffener plate to be over the first side of the circuit board and enabling a bottom side stiffener plate to be under the second side of the circuit board. These enabling steps may be part of the associating step 504 in the method 500. The interconnect cooling loop may be provided, in part, using media paths for the top side stiffener plate and for the bottom side stiffener plate.

The method 500 may include a further step or sub-step, where the media paths extend from a single media path within the computer module. This enables a first media path to reduce, by at least the predetermined threshold, the electrical resistance of first one of the interconnect features on the first side of the circuit board and enables a second media path to reduce, by at least the predetermined threshold, the electrical resistance of a second one of the interconnect features on the second side of the circuit board.

FIG. 5B illustrates yet another process flow or method 550 for a system for dual purpose cooling, in at least one embodiment. Like in the method 500 of FIG. 5A, the device cooling loop in the method 550 of FIG. 5B is in reference to the secondary cooling loop for cooling computing features and the interconnect cooling loop is in reference to interconnect media used to reduce electrical resistance of interconnect features. The method 550 may include providing 552 one or more circuits to receive first information associated with computing features and interconnect features of a computer module. The method 500 may include providing 554, from the one or more circuits and based on the first information, second information for media paths associated with a secondary or device cooling loop and with an interconnect cooling loop. The method 550 may include preparing 556 one or more stiffeners to be associated with a circuit board using a manufacturing sub-system and using the second information.

The method 550 may include determining or verifying 558 that one or more stiffeners are aligned with at least one cold plate and the circuit board. As described with respect to one or more of FIGS. 2A-2D, the alignment in step 558 may be so that the at least one cold plate extends through an area or a provision of the stiffener plate. The method 550 may include preparing 560 the secondary or device cooling loop to cool one or more of the computing features using the at least one cold plate. This step may be in support of the associating step 502 in the method 500 of FIG. 5A. The method 550 may include preparing 562 the interconnect cooling loop to reduce, by at least a predetermined threshold, electrical resistance and/or electrical loss of interconnect features of the computer module. This step may be in support of the associating step 504 in the method 500 of FIG. 5A.

FIG. 6 illustrates an example datacenter 600, in which at least one embodiment from FIGS. 2A-5B may be used. For instance, the example datacenter 600 may be used to support one or more of a design sub-system or a manufacturing sub-system to prepare a secondary or device cooling loop and an interconnect cooling loop as part of dual purpose cooling, and may also benefit from incorporating the dual purpose cooling described throughout herein. The datacenter 600 may also include computer modules subject to the dual purpose cooling described with respect to FIGS. 1-5B herein.

In at least one embodiment, datacenter 600 includes a datacenter infrastructure layer 610, a framework layer 620, a software layer 630, and an application layer 640. In at least one embodiment, such as described in respect to FIGS. 1-5B, features in the dual purpose cooling herein may be performed inside or in collaboration with the example datacenter 600. In at least one embodiment, the infrastructure layer 610, the framework layer 620, the software layer 630, and the application layer 640 may be partly or fully provided via computing components on server trays located in racks 110 of the datacenter. This enables cooling systems of the present disclosure to direct cooling to certain ones of the computing features and the interconnect features, in an efficient and effective manner. Further, aspects of the datacenter, including the datacenter infrastructure layer 610, the framework layer 620, the software layer 630, and the application layer 640 may be used to support selection or design of the intermediate layers for a configurable cold plate as herein discussed with at least reference to FIGS. 1-5B above. As such, the discussion in reference to FIG. 6 may be understood to apply to the hardware and software features required to enable or support a dual purpose cooling herein, for instance.

In at least one embodiment, as in FIG. 6, datacenter infrastructure layer 610 may include a resource orchestrator 612, grouped computing resources 614, and node computing resources (“node C.R.s”) 616(1)-616(N), where “N” represents any whole, positive integer. In at least one embodiment, node C.R.s 616(1)-616(N) may include, but are not limited to, any number of central processing units (“CPUs”) or other processors (including accelerators, field programmable gate arrays (FPGAs), graphics processors, etc.), memory devices (such as dynamic read-only memory), storage devices (such as solid state or disk drives), network input/output (“NW I/O”) devices, network switches, virtual machines (“VMs”), power modules, and cooling modules, etc. In at least one embodiment, one or more node C.R.s from among node C.R.s 616(1)-616(N) may be a server having one or more of above-mentioned computing resources.

In at least one embodiment, grouped computing resources 614 may include separate groupings of node C.R.s housed within one or more racks (not shown), or many racks housed in datacenters at various geographical locations (also not shown). Separate groupings of node C.R.s within grouped computing resources 614 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 612 may configure or otherwise control one or more node C.R.s 616(1)-616(N) and/or grouped computing resources 614. In at least one embodiment, resource orchestrator 612 may include a software design infrastructure (“SDI”) management entity for datacenter 600. In at least one embodiment, resource orchestrator may include hardware, software or some combination thereof.

In at least one embodiment, as shown in FIG. 6, framework layer 620 includes a job scheduler 622, a configuration manager 624, a resource manager 626 and a distributed file system 628. In at least one embodiment, framework layer 620 may include a framework to support software 632 of software layer 630 and/or one or more application(s) 642 of application layer 640. In at least one embodiment, software 632 or application(s) 642 may respectively include web-based service software or applications, such as those provided by Amazon Web Services, Google Cloud and Microsoft Azure. In at least one embodiment, framework layer 620 may be, but is not limited to, a type of free and open-source software web application framework such as Apache Spark™ (hereinafter “Spark”) that may utilize distributed file system 628 for large-scale data processing (such as “big data”). In at least one embodiment, job scheduler 622 may include a Spark driver to facilitate scheduling of workloads supported by various layers of datacenter 600. In at least one embodiment, configuration manager 624 may be capable of configuring different layers such as software layer 630 and framework layer 620 including Spark and distributed file system 628 for supporting large-scale data processing. In at least one embodiment, resource manager 626 may be capable of managing clustered or grouped computing resources mapped to or allocated for support of distributed file system 628 and job scheduler 622. In at least one embodiment, clustered or grouped computing resources may include grouped computing resource 614 at datacenter infrastructure layer 610. In at least one embodiment, resource manager 626 may coordinate with resource orchestrator 612 to manage these mapped or allocated computing resources.

In at least one embodiment, software 632 included in software layer 630 may include software used by at least portions of node C.R.s 616(1)-616(N), grouped computing resources 614, and/or distributed file system 628 of framework layer 620. One or more types of software may include, but are not limited to, Internet web page search software, e-mail virus scan software, database software, and streaming video content software.

In at least one embodiment, application(s) 642 included in application layer 640 may include one or more types of applications used by at least portions of node C.R.s 616(1)-616(N), grouped computing resources 614, and/or distributed file system 628 of framework layer 620. One or more types of applications may include, but are not limited to, any number of a genomics application, a cognitive compute, and a machine learning application, including training or inferencing software, machine learning framework software (such as PyTorch, TensorFlow, Caffe, etc.) or other machine learning applications used in conjunction with one or more embodiments.

In at least one embodiment, any of configuration manager 624, resource manager 626, and resource orchestrator 612 may implement any number and type of self-modifying actions based on any amount and type of data acquired in any technically feasible fashion. In at least one embodiment, self-modifying actions may relieve a datacenter operator of datacenter 600 from making possibly bad configuration decisions and possibly avoiding underutilized and/or poor performing portions of a datacenter.

In at least one embodiment, datacenter 600 may include tools, services, software or other resources to train one or more machine learning models or predict or infer information using one or more machine learning models according to one or more embodiments described herein. In at least one embodiment, in at least one embodiment, a machine learning model may be trained by calculating weight parameters according to a neural network architecture using software and computing resources described above with respect to datacenter 600. In at least one embodiment, trained machine learning models corresponding to one or more neural networks may be used to infer or predict information using resources described above with respect to datacenter 600 by using weight parameters calculated through one or more training techniques described herein. Deep learning may be advanced using any appropriate learning network and the computing capabilities of the datacenter 600. As such, a deep neural network (DNN), a recurrent neural network (RNN) or a convolutional neural network (CNN) may be supported either simultaneously or concurrently using the hardware in the datacenter. Once a network is trained and successfully evaluated to recognize data within a subset or a slice, for instance, the trained network can provide similar representative data for using with the collected data.

In at least one embodiment, datacenter 600 may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as pressure, flow rates, temperature, and location information, or other artificial intelligence services.

Inference and/or training logic 615 may be used to perform inferencing and/or training operations associated with one or more embodiments. In at least one embodiment, inference and/or training logic 615 may be used in system FIG. 6 for inferencing or predicting operations based, at least in part, on weight parameters calculated using neural network training operations, neural network functions and/or architectures, or neural network use cases described herein. In at least one embodiment, inference and/or training logic 615 may include, without limitation, hardware logic in which computational resources are dedicated or otherwise exclusively used in conjunction with weight values or other information corresponding to one or more layers of neurons within a neural network. In at least one embodiment, inference and/or training logic 615 may be used in conjunction with an application-specific integrated circuit (ASIC), such as Tensorflow® Processing Unit from Google, an inference processing unit (IPU) from Graphcore™, or a Nervana® (such as “Lake Crest”) processor from Intel Corp.

In at least one embodiment, inference and/or training logic 615 may be used in conjunction with central processing unit (CPU) hardware, graphics processing unit (GPU) hardware or other hardware, such as field programmable gate arrays (FPGAs). In at least one embodiment, inference and/or training logic 615 includes, without limitation, code and/or data storage modules which may be used to store code (such as graph code), weight values and/or other information, including bias values, gradient information, momentum values, and/or other parameter or hyperparameter information. In at least one embodiment, each of the code and/or data storage modules is associated with a dedicated computational resource. In at least one embodiment, the dedicated computational resource includes computational hardware that further include one or more ALUs that perform mathematical functions, such as linear algebraic functions, only on information stored in code and/or data storage modules, and results from which are stored in an activation storage module of the inference and/or training logic 615.

The datacenter 600 may include the one or more racks with the one or more server trays therein. The datacenter 600 may include one or more computing features and interconnect features in the one or more racks to perform at least part of a workload in the datacenter. The datacenter 600 may include a device cooling loop and an interconnect cooling loop. The device cooling loop may be configured to cool the computing features of the datacenter. The interconnect cooling loop may be configured to reduce, by at least a predetermined threshold, electrical resistance and/or electrical loss of the interconnect features in the datacenter.

In the following description, numerous specific details are set forth to provide a more thorough understanding of at least one embodiment. However, it will be apparent to one skilled in the art that the inventive concepts may be practiced without one or more of these specific details.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. In at least one embodiment, use of term “set” (e.g., “a set of items”) or “subset” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present. In addition, unless otherwise noted or contradicted by context, term “plurality” indicates a state of being plural (e.g., “a plurality of items” indicates multiple items). In at least one embodiment, number of items in a plurality is at least two, but can be more when so indicated either explicitly or by context. Further, unless stated otherwise or otherwise clear from context, phrase “based on” means “based at least in part on” and not “based solely on.”Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors.

In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause computer system to perform operations described herein. In at least one embodiment, set of non-transitory computer-readable storage media comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors—for example, a non-transitory computer-readable storage medium store instructions and a main central processing unit (“CPU”) executes some of instructions while a graphics processing unit (“GPU”) executes other instructions. In at least one embodiment, different components of a computer system have separate processors and different processors execute different subsets of instructions.

In at least one embodiment, an arithmetic logic unit is a set of combinational logic circuitry that takes one or more inputs to produce a result. In at least one embodiment, an arithmetic logic unit is used by a processor to implement mathematical operation such as addition, subtraction, or multiplication. In at least one embodiment, an arithmetic logic unit is used to implement logical operations such as logical AND/OR or XOR. In at least one embodiment, an arithmetic logic unit is stateless, and made from physical switching components such as semiconductor transistors arranged to form logical gates. In at least one embodiment, an arithmetic logic unit may operate internally as a stateful logic circuit with an associated clock. In at least one embodiment, an arithmetic logic unit may be constructed as an asynchronous logic circuit with an internal state not maintained in an associated register set. In at least one embodiment, an arithmetic logic unit is used by a processor to combine operands stored in one or more registers of the processor and produce an output that can be stored by the processor in another register or a memory location.

In at least one embodiment, as a result of processing an instruction retrieved by the processor, the processor presents one or more inputs or operands to an arithmetic logic unit, causing the arithmetic logic unit to produce a result based at least in part on an instruction code provided to inputs of the arithmetic logic unit. In at least one embodiment, the instruction codes provided by the processor to the ALU are based at least in part on the instruction executed by the processor. In at least one embodiment combinational logic in the ALU processes the inputs and produces an output which is placed on a bus within the processor. In at least one embodiment, the processor selects a destination register, memory location, output device, or output storage location on the output bus so that clocking the processor causes the results produced by the ALU to be sent to the desired location.

Accordingly, in at least one embodiment, computer systems are configured to implement one or more services that singly or collectively perform operations of processes described herein and such computer systems are configured with applicable hardware and/or software that allow performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to practice of disclosure.

In description and claims, terms “coupled” and “connected,” along with their derivatives, may be used. It should be understood that these terms may be not intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, “processor” may be a CPU or a GPU. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. In at least one embodiment, terms “system” and “method” are used herein interchangeably insofar as system may embody one or more methods and methods may be considered a system.

In present document, references may be made to obtaining, acquiring, receiving, or inputting analog or digital data into a subsystem, computer system, or computer-implemented machine. In at least one embodiment, process of obtaining, acquiring, receiving, or inputting analog and digital data can be accomplished in a variety of ways such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from providing entity to acquiring entity. References may also be made to providing, outputting, transmitting, sending, or presenting analog or digital data. In at least one embodiment, processes of providing, outputting, transmitting, sending, or presenting analog or digital data can be accomplished by transferring data as an input or output parameter of a function call, a parameter of an application programming interface or interprocess communication mechanism.

Although descriptions herein set forth example implementations of described techniques, other architectures may be used to implement described functionality, and are intended to be within scope of this disclosure. Furthermore, although specific distributions of responsibilities may be defined above for purposes of description, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A system, comprising:
a device cooling loop configured to cool computing features of a computer module; and
an interconnect cooling loop configured to reduce, by at least a predetermined threshold, electrical resistance and/or electrical loss of interconnect features of the computer module.

2. The system of claim 1, wherein the device cooling loop is associated with one or more cold plates for one or more of a central processing unit (CPU) or a graphics processing unit (GPU), and wherein the interconnect cooling loop is associated with a thermally conductive line for the interconnect features associated with the CPU or the GPU or that is between the CPU and the GPU.

3. The system of claim 1, wherein each of the device cooling loop and the interconnect cooling loop define a fluid path having different device media.

4. The system of claim 1, wherein each of the device cooling loop and the interconnect cooling loop operate at different temperatures, pressures, and flow rates.

5. The system of claim 1, wherein the device cooling loop is associated with a device media having a device exit temperature and wherein the interconnect cooling loop is associated with an interconnect media having an interconnect exit temperature, wherein a difference between the device exit temperature and the interconnect exit temperature is at least 100° C.

6. The system of claim 5, wherein the device cooling loop is associated with a device media having an exit temperature of above 0 degrees centigrade (° C.) and wherein the interconnect cooling loop is associated with an interconnect media having an exit temperature of less than −100° C.

7. The system of claim 6, wherein the device media and the interconnect media are a same media used serially or subsequently and undergo a two-phase transformation process.

8. The system of claim 1, wherein the device cooling loop is associated with a device media having an inlet temperate of less than 0° C. and above −100° C. and wherein the interconnect cooling loop is associated with an interconnect media having an inlet temperature of less than −100° C.

9. The system of claim 1, wherein the interconnect cooling loop is configured in a series configuration with respect to the device cooling loop, wherein the series configuration enables heat exchange between the device cooling loop and the interconnect cooling loop, and wherein an interconnect media used in the interconnect cooling loop is in a first state to perform the reduction in the electrical resistance of the interconnect features and is in a second state or undergoes a phase change from the first state to the second state to perform the heat exchange with the device cooling loop.

10. The system of claim 1, further comprising:
one or more cold plates in the device cooling loop and associated with at least one of the computing features to absorb heat from the at least one of the computing features; and
one or more metal lines in the interconnect cooling loop to align with the interconnect features and to enable the reduction, by at least the predetermined threshold, of the electrical resistance of the interconnect features.

11. The system of claim 1, further comprising:
a pump or directional valves to support a single phase or a two-phase media in the interconnect cooling loop, wherein the pump or the direction valves are controlled based in part on an input from a control system associated with the interconnect cooling loop.

12. The system of claim 1, further comprising:
a circuit board comprising the interconnect features on a first side and on a second side of the circuit board;
a top side stiffener plate over the first side of the circuit board; and
a bottom side stiffener plate under the second side of the circuit board, wherein the interconnect cooling loop is provided using media paths for the top side stiffener plate and for the bottom side stiffener plate.

13. The system of claim 12, wherein the media paths extend from a single media path within the computer module to reduce, by at least the predetermined threshold, the electrical resistance of first one of the interconnect features on the first side of the circuit board and of second one of the interconnect features on the second side of the circuit board.

14. A system comprising:
one or more circuits to receive first information associated with computing features and interconnect features of a computer module and to provide second information for media paths associated with a device cooling loop and an interconnect cooling loop within the computer module; and
a manufacturing sub-system to prepare, using the second information, one or more stiffener plates to be associated with a circuit board having the computing features and the interconnect features, to prepare the device cooling loop to cool one or more of the computing features using at least a cold plate, and to prepare the interconnect cooling loop to reduce, by at least a predetermined threshold, electrical resistance of interconnect features of the computer module.

15. The system of claim 14, wherein the first information comprises one or more of a first layout of the computing features and the interconnect features, a type of the computing features and the interconnect features, or predetermined heat or electrical specifications associated with the computing features and with the interconnect features, and wherein the second information comprises one or more of a second layout for the media paths comprising at least the interconnect cooling loop, a flow rate for at least an interconnect media of the interconnect cooling loop, or a predetermined phase or temperature range for the interconnect media.

16. The system of claim 14, wherein the one or more circuits is further to provide the predetermined threshold for reduction in the electrical resistance of at least one of the interconnect features based in part on the first information and is further to determine one or more of a flow rate and one or more inlet and exit temperatures to be associated with interconnect cooling loop.

17. The system of claim 14, wherein the one or more circuits is further to receive the predetermined threshold for reduction in the electrical resistance of the at least one of the interconnect features based in part on the first information indicating that the at least one of the interconnect features is a high-speed interface between one or more of the computing features of the computer module.

18. A method, comprising:
cooling, using a device cooling loop, computing features of a computer module; and
reducing, by at least a predetermined threshold and using an interconnect cooling loop, electrical resistance and/or electrical loss of interconnect features of the computer module.

19. The method of claim 18, wherein the device cooling loop is associated with a secondary media having an exit temperature of above 0 degrees centigrade (° C.) and wherein the interconnect cooling loop is associated with an interconnect media having an exit temperature of less than −100° C.

20. The method of claim 18, wherein the device cooling loop is associated with a secondary media having an inlet temperate of less than 0° C. and above −100° C. and wherein the interconnect cooling loop is associated with an interconnect media having an inlet temperature of less than −100° C.

21. The method of claim 18, further comprising
providing the interconnect cooling loop in a series configuration with the device cooling loop; and
enabling, using the series configuration, heat exchange between the device cooling loop and the interconnect cooling loop, and wherein an interconnect media used in the interconnect cooling loop is in a first state to perform the reduction in the electrical resistance of the interconnect features and is in a second state or undergoes a phase change from the first state to the second state to perform the heat exchange with the device cooling loop.

22. The method of claim 18, further comprising:
using one or more cold plates in the device cooling loop and associated with at least one of the computing features to absorb heat from the at least one of the computing features; and
aligning one or more metal lines in the interconnect cooling loop with the interconnect features to enable the reduction, by at least the predetermined threshold, of the electrical resistance of the interconnect features.

23. The method of claim 18, further comprising:
adjusting, using a pump or directional valves, a single phase or a two-phase media in the interconnect cooling loop; and
controlling the pump or the direction valves based in part on an input from a control system associated with the interconnect cooling loop.

24. The method of claim 18, further comprising:
providing a circuit board comprising the interconnect features on a first side and on a second side of the circuit board;
enabling a top side stiffener plate to be over the first side of the circuit board; and
enabling a bottom side stiffener plate to be under the second side of the circuit board, wherein the interconnect cooling loop is provided, in part, using media paths for the top side stiffener plate and for the bottom side stiffener plate.

25. The method of claim 24, wherein the media paths extend from a single media path within the computer module to reduce, by at least the predetermined threshold, the electrical resistance of first one of the interconnect features on the first side of the circuit board and of second one of the interconnect features on the second side of the circuit board.

26. A first closed cooling loop provided in parallel and to work concurrently with a second closed cooling loop within infrastructure of a datacenter, the first closed cooling loop comprising a first pumped cooling media to extract heat from computing features in the infrastructure and the second closed cooling loop comprising a second pumped cooling media to reduce, by a predetermined threshold, electrical resistance and/or electrical loss of interconnect features in the infrastructure.

27. A datacenter comprising:
one or more racks comprising one or more server trays;
one or more computing features and interconnect features in the one or more racks to perform at least part of a workload in the datacenter;
a device cooling loop configured to cool the computing features; and
an interconnect cooling loop configured to reduce, by at least a predetermined threshold, electrical resistance and/or electrical loss of the interconnect features.
